(19) United States
(12) Patent Application Publication
(10) Pub. No.: US 2017/0249162 A1
(43) Pub. Date: Aug. 31, 2017

(54) SAFE TRANSMIT PACKET PROCESSING FOR NETWORK FUNCTION VIRTUALIZATION APPLICATIONS

(71) Applicant: Red Hat Israel, Ltd., Ra'anana (IL)

(72) Inventor: Michael Tsirkin, Yokneam Illit (IL)

(21) Appl. No.: 15/053,415

(22) Filed: Feb. 25, 2016

(51) Int. Cl. G06F 9/44; G11C 7/10; G06F 15/177; G06F 12/10; G06F 15/78

(52) U.S. Cl. CPC G06F 9/4411; G06F 12/1081; G06F 15/7825; G06F 15/177; G06F 12/1009; G11C 7/1072; G06F 9/4406; G06F 2212/657; G06F 2212/70

(57) ABSTRACT

A transmit packet processing system includes a NIC, a memory, one or more processors in communication with the memory, and a device driver. The memory has a first set and a second set of physical memory pages. The device driver is loaded in an OS and is configured to initialize the NIC. The device driver is further configured to assign a plurality of rings to specific physical memory pages. The plurality of rings includes transmit rings and receive rings. The transmit rings are utilized by an application in the application memory space. The transmit rings are assigned to the first set of physical memory pages which are writable by the application. The receive rings are assigned to the second set of physical memory pages which are not writable by the application. The device driver is further configured to initiate a mapping of the transmit rings into the application memory space.

### BACKGROUND

Computer systems may require packet processing for packets sent to and from applications in the users pace. A computer system may run applications and processes used in Network Function Virtualization (NFV). The computer system may use kernel bypass to process networking packets in the application memory space in order to avoid the overhead of communicating with the kernel and operating system (OS). For example, a Network Interface Controller (NIC) may transmit and receive packets by Direct Memory Access (DMA) in Random Access Memory (RAM). The NIC may retrieve packet addresses from a device ring or device rings. The transmit status and receive status may be written into the rings to allow for packet processing.

### SUMMARY

The present disclosure provides new and innovative systems and methods for transmit packet processing. In an example embodiment, a system includes a NIC, a memory, one or more processors in communication with the memory, and a device driver. The memory has a first set of physical memory pages and a second set of physical memory pages. The device driver is configured to initialize the NIC. The device driver is loaded in an operating system by a kernel of the OS. The device driver is further configured to assign a plurality of rings to specific physical memory pages. The plurality of rings include transmit rings and receive rings, and one or more of the transmit rings are utilized by an application in an application memory space. The transmit rings are assigned to the first set of physical memory pages. The first set of physical memory pages is writable by the application. The receive rings are assigned to the second set of physical memory pages. The second set of physical memory pages is not writeable by the application. The device driver is further configured to initiate a mapping of the transmit rings into the application memory space.

In an example embodiment, a method of packet processing includes initializing, by a device driver, a NIC. The device driver is loaded in an OS by a kernel of the OS. The method further includes assigning, by the device driver, a plurality of rings to use specific physical memory pages. The plurality of rings include transmit rings and receive rings. One or more of the transmit rings are utilized by an application in the application memory space. The transmit rings are assigned to a first set of physical memory pages. A first page of the first set of physical pages is writeable by the application. The receive rings are assigned to a second set of physical memory pages. A second page of the second set of physical memory pages is not writable by the application. The method further includes initiating, by the device driver, a mapping of the transmit rings into the application memory space.

In an example embodiment, a non-transitory machine readable medium storing code which, when executed by a computer system, cause the computer system to load, by a kernel, a device driver in an operating system. The non-transitory machine readable medium further causes the computer system to initialize, by the device driver, a network interface controller. The non-transitory machine readable medium further causes the computer system to assign, by the device driver, transmit rings to a first set of physical memory pages. The non-transitory machine readable medium further causes the computer system to assign, by the device driver, receive rings to a second set of physical memory pages. The non-transitory machine readable medium further causes the computer system to initiate, by the device driver, a mapping of the transmit rings into an application memory space.

Additional features and advantages of the disclosed method and apparatus are described in, and will be apparent from, the following Detailed Description and the Figures. The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the inventive subject matter.

### BRIEF DESCRIPTION OF THE FIGURES

FIG. 1 illustrates a block diagram of an example transmit packet processing system according to an example embodiment of the present disclosure.

FIG. 2 illustrates a block diagram of an example memory device with transmit rings and receive rings according to an example embodiment of the present disclosure.

FIG. 3 illustrates a block diagram of an example page table according to an example embodiment of the present disclosure.

FIG. 4 illustrates a flowchart of an example process for transmit packet processing according to an example embodiment of the present disclosure.

FIG. 5 illustrates a flow diagram of an example process for transmit packet processing according to an example embodiment of the present disclosure.

### DETAILED DESCRIPTION OF EXAMPLE EMBODIMENTS

Techniques are disclosed for providing safe transmit packet processing for applications such as network function virtualization applications. In an example embodiment, a transmit packet processing system includes an operating system, a kernel, a device driver, and one or more interconnected nodes in a kernel space. Additionally, the transmit packet processing system may include one or more applications operating in an application memory space. The transmit packet processing system allows transmit packet processing without the need to use kernel bypass to process networking packets in application memory space.

Other methods of processing networking packets (e.g., transmit packets) include kernel bypass and Direct Memory Access (DMA). For example, a typical Network Interface Controller (NIC) may transmit and receives packets by DMA in Random Access Memory (RAM) where packet addresses are retrieved from a device ring. Then, the transmit and receive status may be written into the ring. However, application memory space access to the device rings allow the application memory space to crash the kernel and results in a system with limited security because applications in the application memory space may directly access memory available to the application memory space. For example, a crash may result from a situation in which a program such as a user application stops performing its expected functions and/or responding to other parts of the computer system. During a crash, the program or user application may appear to a user to freeze. Additionally, a crash may cause the entire computer system to stall or shut down.

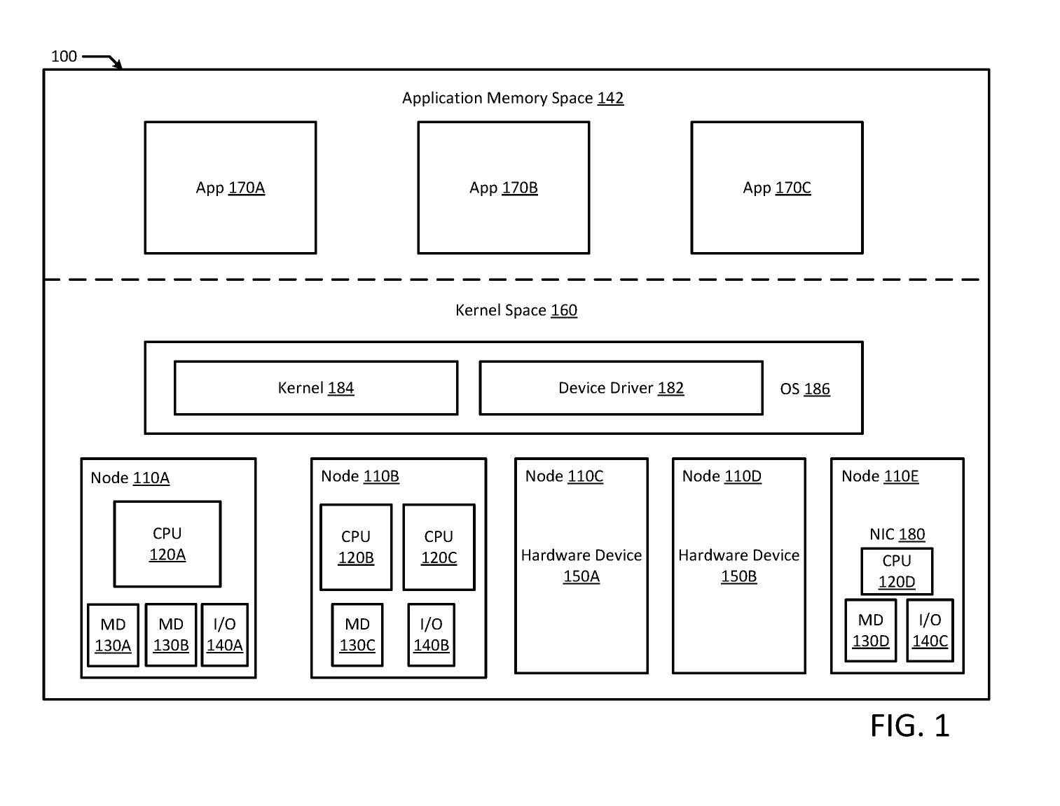

FIG. 1 depicts a high-level component diagram of an example transmit packet processing system 100 in accordance with one or more aspects of the present disclosure. The packet processing system 100 may include a network interface controller 180, a memory (e.g., MD 120A-D), and an operating system (OS) 186. The OS 186 may include a kernel 184 and a device driver 182.

The kernel 184 may be a program. For example, the kernel 184 may be a program that constitutes the core of the operating system 186. As used herein, the kernel 184 may refer to a privileged software component with the ability to change memory mappings for an application (e.g., Applications 170A-C). Additionally, the kernel 184 may act as a controller of multiple processes including individual user processes within the application memory space 142. For example, the kernel 184 may perform several tasks such as executing processes and handling interrupts in the kernel space 160. Additionally a user may run programs or applications (e.g., Applications 170A-C) in the application memory space 142. An application (e.g., Applications 170A-C) may be an application in userspace, an application in a virtual machine, or an application located elsewhere, all of which make up the application memory space 142. As used herein, an application (e.g., Applications 170A-C) may refer to less privileged software without the ability to change memory mappings for itself. The kernel 184 may provide basic services for the operating system 186 that are requested by other parts of the operating system or by application programs through system calls. For example, the kernel 184 may provide basic services such as memory management, process management, file management, and I/O management.

In various example embodiments, the kernel 184 may be a monolithic kernel, a microkernel, a hybrid kernel, or an exokernel. Additionally, the kernel 184 may include a scheduler, a supervisor, an interrupt handler, and a memory manager. In an example embodiment, the scheduler may determine the order various processes are handled on the kernel 184. Additionally, the scheduler may determine how various processes share the kernel's processing time. In an example embodiment, the supervisor may grant use of the computer system to each process after it is scheduled by the scheduler. Additionally, the interrupt handler may handle requests from various hardware devices (e.g., Hardware Devices 150A-B) that require the kernel's service. The memory manager may allocate the system's address spaces (e.g., locations in memory) to the users of the kernel's services.

The packet processing system 100 may include one or more interconnected nodes 110A-E. Each node 110A-B may in turn include one or more physical processors (e.g., CPU 120A-C) communicatively coupled to memory devices (e.g., MD 130A-C) and input/output devices (e.g., I/O 140A-C). Each node 110C-D may include a hardware device 150A-B. In an example embodiment, a hardware device (e.g., 150A-B) may include a network device (e.g., a network adapter or any other component that connects a computer to a computer network), a peripheral component interconnect (PCI) device, storage devices, disk drives, sound or video adaptors, photo/video cameras, printer devices, keyboards, displays, etc. A node 110E may be a network interface controller 180. Network interface controller 180 may include a processor (e.g., CPU 120D), a memory (e.g., memory device 130D), and an input output device (e.g., I/O 140C). The packet processing system 100 may also include one or more applications (e.g., Applications 170A-C) operating within application memory space 142.

As used herein, physical processor or processor 130A-D refers to a device capable of executing instructions encoding arithmetic, logical, and/or I/O operations. In one illustrative example, a processor may follow Von Neumann architectural model and may include an arithmetic logic unit (ALU), a control unit, and a plurality of registers. In a further aspect, a processor may be a single core processor which is typically capable of executing one instruction at a time (or process a single pipeline of instructions), or a multi-core processor which may simultaneously execute multiple instructions. In another aspect, a processor may be implemented as a single integrated circuit, two or more integrated circuits, or may be a component of a multi-chip module (e.g., in which individual microprocessor dies are included in a single integrated circuit package and hence share a single socket). A processor may also be referred to as a central processing unit (CPU).

As discussed herein, a memory device 130A-D refers to a volatile or non-volatile memory device, such as RAM, ROM, EEPROM, or any other device capable of storing data. As discussed herein, I/O device 150A-C refers to a device capable of providing an interface between one or more processor pins and an external device capable of inputting and/or outputting binary data.

Processors 120A-D may be interconnected using a variety of techniques, ranging from a point-to-point processor interconnect, to a system area network, such as an Ethernet-based network. Local connections within each node, including the connections between a processor 120A-D and a memory device 130A-D may be provided by one or more local buses of suitable architecture, for example, peripheral component interconnect (PCI).

In an example embodiment, the device driver 182 may be loaded in the OS 186 by the kernel 184. The device driver 182 may be a program that allows the operating system to interact with hardware devices. The device driver 182 may be configured to initialize the NIC 180. In an example embodiment, the device driver 182 may also be configured to assign a plurality of rings to specific physical memory pages. The transmit rings may be utilized by an application (e.g., Applications 170A-C) in the application memory space 142. The specific physical memory pages may have different access rights to increase security of the plurality of rings. For example, some physical memory pages may not be writable by an application (e.g., Applications 170A-C) in the application memory space 142, which may increase security of the system and may prevent an application (e.g., Applications 170A-C) from crashing the kernel 184.

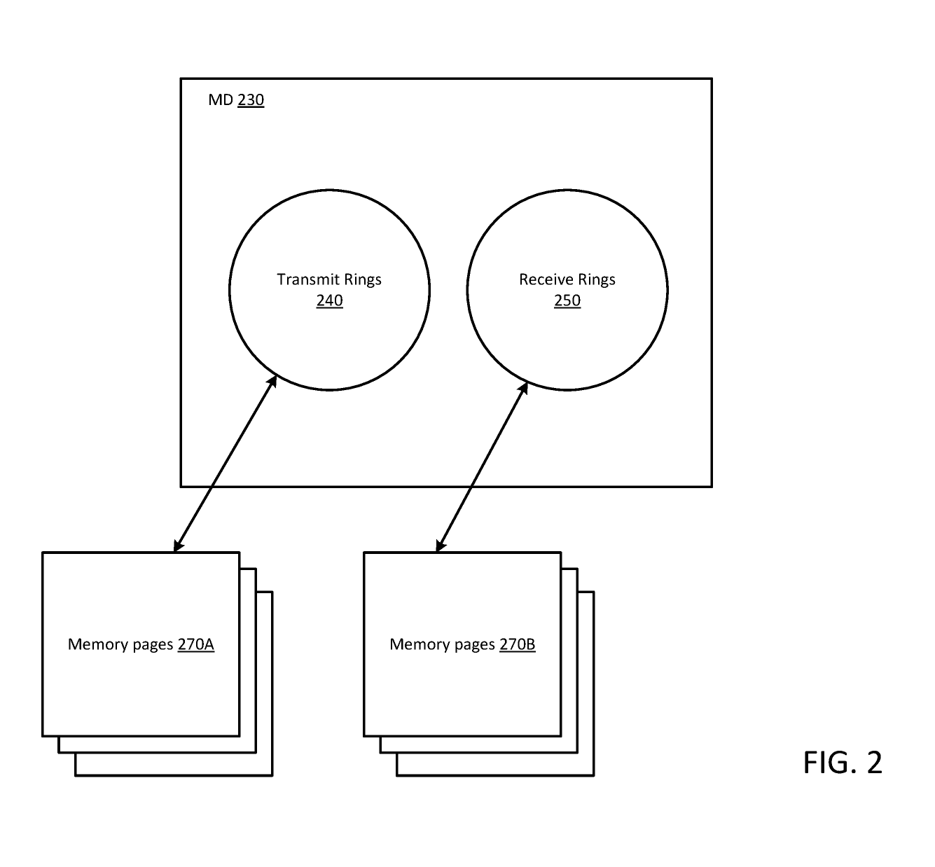

FIG. 2 depicts a high-level component diagram of an example memory device 230. In an example embodiment, the memory device 230 may include a plurality of rings such as transmit rings 240 and receive rings 250. In an example embodiment, the plurality of rings may be located in the NIC 180. In another example embodiment, the plurality of rings may be located in memory available to the application memory space 142. In an example embodiment, the memory device 230 may include a single transmit ring and one or more receive rings 250. In another example embodiment, the memory device 230 may include a single receive ring and one or more transmit rings 240. In another example embodiment, the memory device may include one receive ring and one transmit ring. Any other suitable combination of rings for packet processing may be included in the memory device 230. The transmit rings 240 may be assigned to a first set of physical memory pages 270A. Additionally, the receive rings 250 may be assigned to a second set of physical memory pages 270B. In an example embodiment, the first set of physical memory pages 270A may be writable by the application 170. Additionally, the second set of physical memory pages 270B may not be writeable by the application 170. Preventing the application 170 from writing into the receive rings 250 or second set of physical memory pages 270B ensures that the application 170 cannot intentionally or inadvertently corrupt machine memory, which may lead to crashing the kernel 184.

In an example embodiment, an input/output memory management unit (IOMMU) may be programmed to allow a device read access of all of machine memory (e.g., memory available to OS 186). The receive rings 250, which are associated with the second set of physical memory pages 270B may only allow read access. The receive rings 250 may store incoming packets that may be processed by the device driver 182 and sent through the kernel 184. For example, the second set of physical memory pages 270B may not be writeable by the device, and may only allow read access, which may advantageously prevent the device from corrupting machine memory.

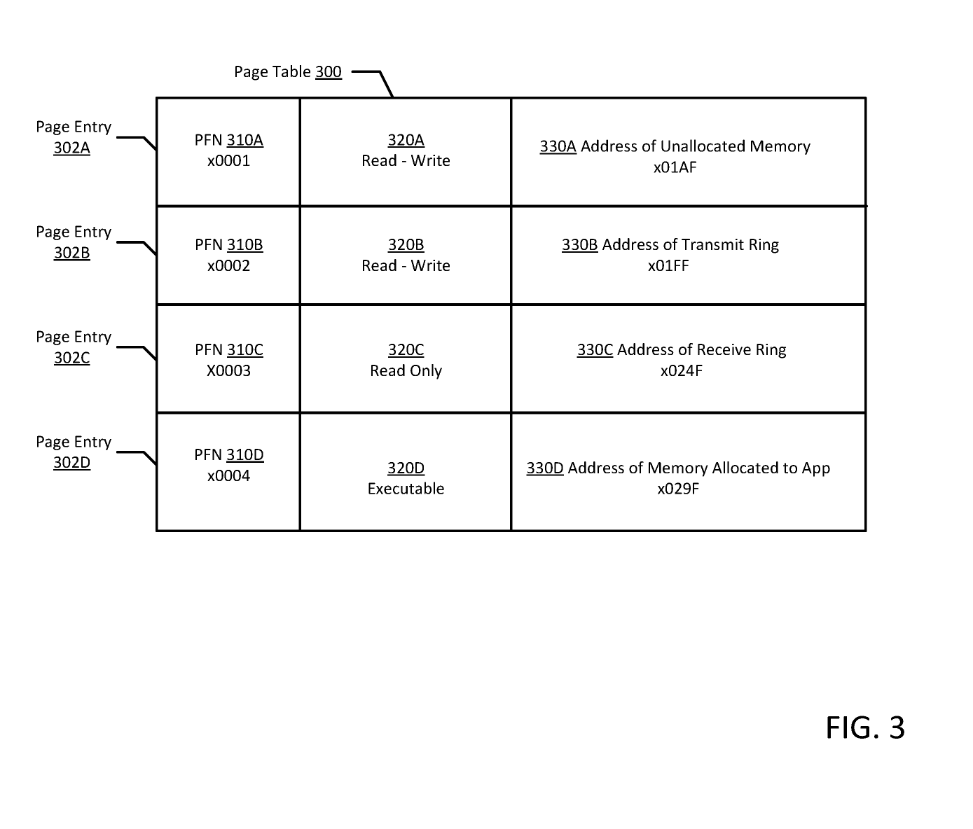

FIG. 3 illustrates a block diagram of a page table 300 according to an example embodiment of the present disclosure. In an example embodiment, the page table 300 may be a CPU page table. In general, the OS 186 may manage the memory usage of the applications 170A-C. The physical memory associated with the applications 170A-C may be divided into pages, which are identified with a unique number (e.g., Page Frame Number (PFN) 310A-D).

A page table 300 is a data structure that may be used to store a mapping of memory addresses of the transmit rings 240 to memory addresses of the memory available to the application memory space 142. Accordingly, address translation may be handled using page tables 300. In an example embodiment, the page table 300 stores a mapping of virtual address to physical addresses. In an example embodiment, a computer or CPU may run a virtual machine by executing a software layer above a hardware and below the virtual machine. A virtual machine may be presented as a virtualized physical layer, including processors, memory, and I/O devices. For example, a virtual machine may include virtual processors, virtual memory devices, and/or virtual I/O devices. A virtual machine may execute a guest operating system, which may utilize the virtual processors, virtual memory devices, and/or virtual I/O devices. Additionally, a virtual machine may include one or more applications that run on the virtual machine under the guest operating system. A virtual machine may run on any type of dependent, independent, compatible, and/or incompatible applications on the underlying hardware and OS. In an example embodiment, applications run on a virtual machine may be dependent on the underlying hardware and/or OS. In another example embodiment, applications run on a virtual machine may be independent of the underlying hardware and/or OS. For example, applications run on a first virtual machine may be dependent on the underlying hardware and/or OS while applications run on a second virtual machine are independent of the underlying hardware and/or OS. Additionally, applications run on a virtual machine may be compatible with the underlying hardware and/or OS. In an example embodiment, applications run on a virtual machine may be incompatible with the underlying hardware and/or OS. For example, applications run on one virtual machine may be compatible with the underlying hardware and/or OS while applications run on another virtual machine are incompatible with the underlying hardware and/or OS. In an example embodiment, a device may be implemented as a virtual machine.

The page table 300 comprises page entries 302A-D that map PFN 310A-D (e.g., an address of memory in application memory space 142) with an address 330A-D (e.g., an address of the transmit rings 240). Page tables 300 may be used together with any paging data structure to support translation between addresses (e.g., 32-bit linear address space using a two-level hierarchical paging structure, Physical Address Extension mode, INTEL Extended Memory 64 Technology mode, etc.). In an example embodiment, page tables 300 may include protection identifiers 320A-D that indicate an access status for each of the pages.

In an example embodiment, page tables 300 may include a protection identifier 320A-D. The protection identifier 320A-D indicates the access status of a page corresponding to the page entry 302A-D of the page table 300. For example, a protection identifier 320A-D may be used to define that a given page is writable (or read-write), write-protected (or read-only), executable (or executable and readable), executable only, etc. For example, as illustrated in the example embodiment in FIG. 3, the page corresponding to page entry 302A, PFN 310A address (x0001), address 330A (x01AF), and protection identifier 320A has been defined in page table 300 as ‘Read-Write’. Page entry 302B may correspond to the transmit rings 240 associated with the first set of physical memory pages 270A. For example, the first set of physical memory pages 270A may be writable by the application 170 such that the protection identifier is ‘Read-Write’. Additionally, page entry 302C may correspond to the receive rings 250 associated with the second set of physical memory pages 270B. For example, the second set of physical memory pages 270B may not be writable by the application 170 such that the protection identifier is ‘Read Only’. In an example embodiment, the NIC 180 may be used to modify a protection identifier 320A-D of various pages. In addition, the page table 300 may include additional information not shown in FIG. 3 including statistics information, background information, dirty identifiers which indicate that modifications to a page must be written back to disk, etc.

In an example embodiment, one or more page tables 300 may be maintained by the NIC 180. The page tables may map transmit ring addresses to addresses that are accessible by the applications (e.g., Applications 170A-C), the OS 186, and/or the OS 186 resources. The sizes of different page tables may vary and may include more or fewer entries than are illustrated in FIG. 3.

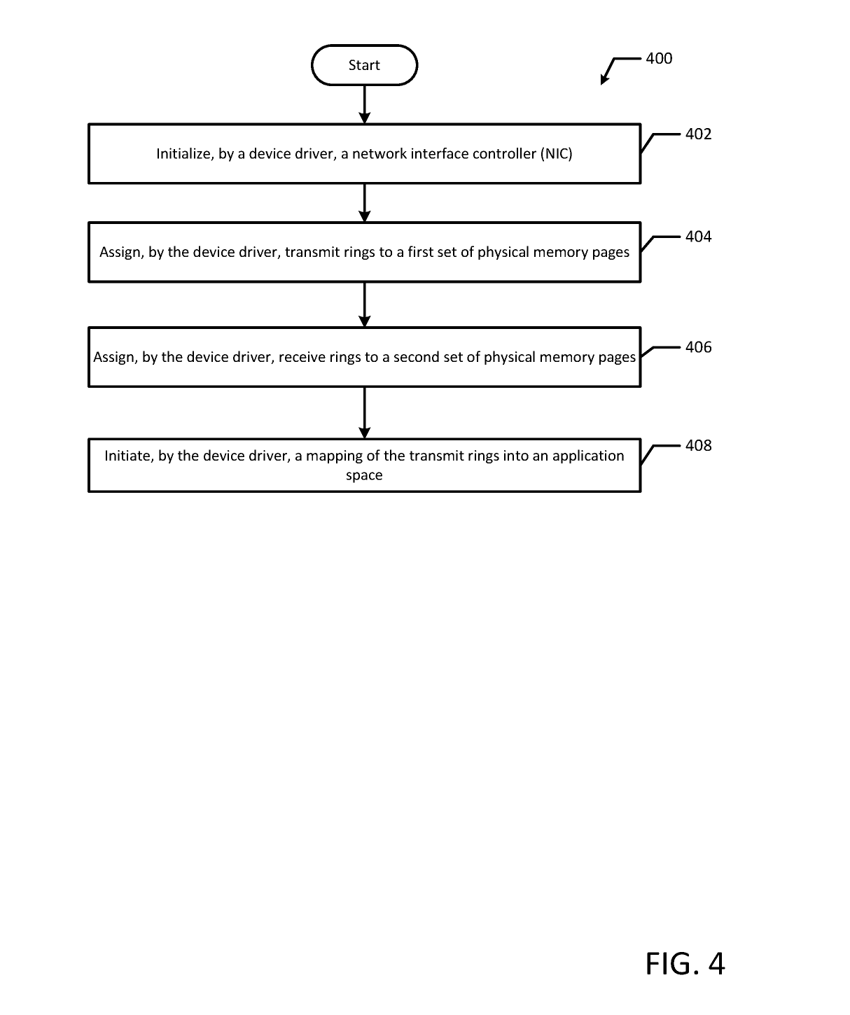

FIG. 4 illustrates a flowchart of an example method 400 for transmit packet processing in accordance with an example embodiment of the present disclosure. Although the example method 400 is described with reference to the flowchart illustrated in FIG. 4, it will be appreciated that many other methods of performing the acts associated with the method 400 may be used. For example, the order of some of the blocks may be changed, certain blocks may be combined with other blocks, and some of the blocks described are optional. The method 400 may be performed by processing logic that may comprise hardware (circuitry, dedicated logic, etc.), software, or a combination of both.

In the illustrated embodiment, a device driver 182 may initialize a NIC 180 (block 402). In an example embodiment, the device driver 182 may be loaded in an operating system 186 by a kernel 184 of the OS 186. Then, the device driver 182 may assign transmit rings 240 to a first set of physical memory pages 270A (block 404). In an example embodiment, there may be one transmit ring 240 or multiple transmit rings 240. The transmit rings 240 may be utilized by an application (e.g., Applications 170A-B) in the application memory space 142. In an example embodiment, the device driver 182 may assign a transmit ring to a first set of physical memory pages 270A. The first set of physical memory pages 270A may be writable by the application 170. In another example embodiment, a first page of the first set of physical memory pages 270A may be writable by the application 170 and one of the other pages of the first set of physical memory pages 270A may have an undefined access permission. For example, the transmit ring may not require all the memory pages in the first set of physical memory pages. The unused pages may not have an established access permission. The device driver 182 may assign receive rings 250 to a second set of physical memory pages 270B (block 406). The receive rings 250 may store incoming packets that may be processed by the device driver 182 and sent through the kernel 184. In an example embodiment, the second set of physical memory pages 270B may not be writable by the application 170, which may prevent the application 170 from crashing the kernel. In another example embodiment, a second page of the second set of physical memory pages 270B may not be writable by the application 170 and one of the other pages of the second set of physical memory pages 270B may not have an access permission established. Then, the device driver 182 may initiate a mapping of the transmit rings 240 into an application memory space 142 (block 408). In an example embodiment, initiating the mapping by the device driver 182 may include sending, by the device driver 182, a mapping request to the kernel 184. Responsive to the device driver 182 sending the mapping request, the kernel 184 may receive the mapping request from the device driver 182. Then, the kernel 184 may map the transmit rings 240 into the application memory space 142 as discussed further below.

In an example embodiment, the device driver 182 may restrict access to the second set of physical memory pages 270B. For example, the device driver 182 may restrict access to the second set of physical memory pages 270B to a specific type of access by the application 170 in the application memory space 142. For example, the specific type of access may be read only access, which may advantageously increase the security of the system by preventing the application 170 or a device from writing into the second set of physical memory pages 270B. In an example embodiment, the mapping may include a page table 300 that maps virtual addresses to physical addresses. Additionally, the page table 300 may include access permissions included as protection identifiers (e.g., protection identifiers 320A-D). In an example embodiment, the device driver 182 may map a transmit request address into the application 170. The transmit request address may be located on the NIC 180.

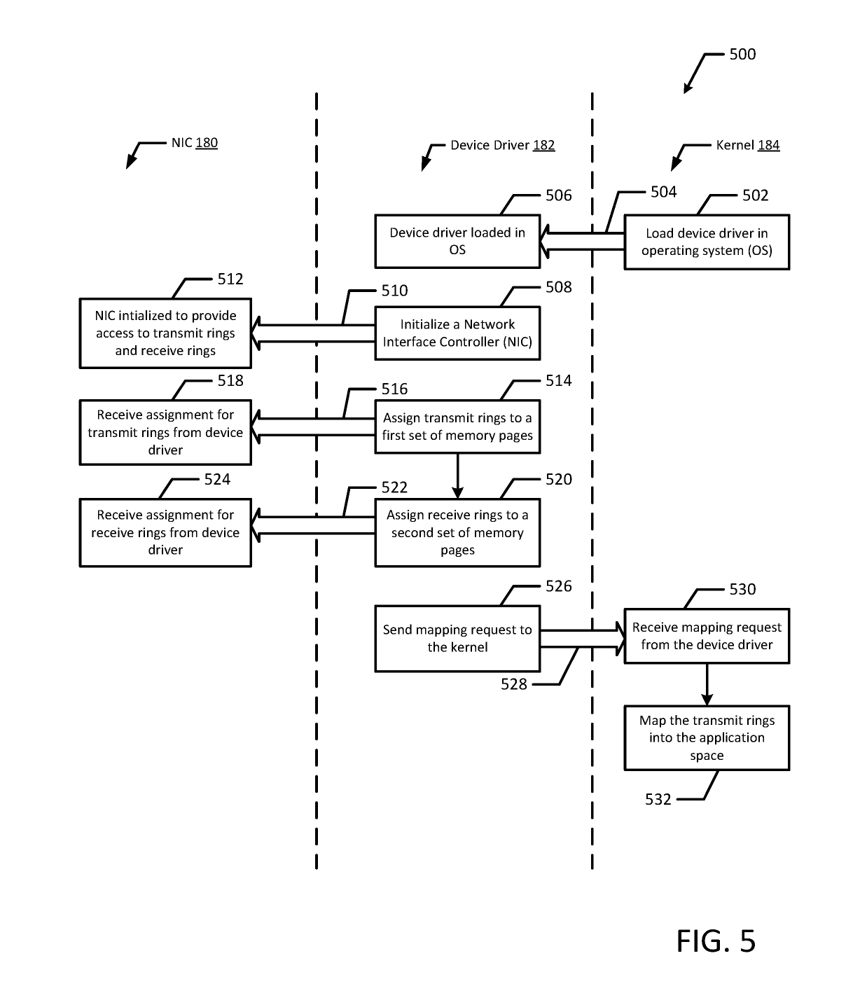

FIG. 5 depicts a flow diagram illustrating an example method 500 for transmit packet processing according to an example embodiment of the present disclosure. Although the example method 500 is described with reference to the flow diagram illustrated in FIG. 5, it will be appreciated that many other methods of performing the acts associated with the method may be used. For example, the order of some of the blocks may be changed, certain blocks may be combined with other blocks, and some of the blocks described are optional. The method may be performed by processing logic that may comprise (e.g., circuity, dedicated logic, etc.), software, or a combination of both.

In the illustrated example embodiment, a kernel 184 loads a device driver 182 in an operating system (OS) 186 (blocks 502 and 504). In an example embodiment, the kernel 184 may be a program that controls processes of the operating system. For example, the kernel scheduler may load the device driver 182 in the OS 186. The device driver 182 is loaded in the operating system (block 506). The device driver 182 may be a program that allows the OS 186 to interact with hardware devices. For example, the device driver 182 may allow the OS 186 to interact with NIC 180. The device driver 182 may initialize NIC 180 (blocks 508 and 510). In an example embodiment, the NIC 180 may include a plurality of rings. For example, the NIC 180 may include transmit rings 240 and receive rings 250. The NIC 180 may be initialized to provide access to transmit rings 240 and receive rings 250 (block 512). The device driver 182 may assign the transmit rings 240 to a first set of physical memory pages 270A (block 514). The device driver 182 may also notify the NIC 180 that the transmit rings 240 are assigned to a first set of physical memory pages 270A (block 516). In an example embodiment, the first set of physical memory pages 270A may be writable by the application 170. For example, the first set of physical memory pages 270A may include an access permission or protection identifier 320 as ‘Read-Write’. Then, the NIC 180 may receive the assignment associated with the transmit rings 240 from the device driver 182 (block 518). The device driver 182 may also assign receive rings 250 to a second set of physical memory pages 270B (block 520). The device driver 182 may also notify the NIC that the receive rings 250 are assigned to a second set of physical memory pages 270B (block 522). In an example embodiment, the second set of physical memory pages 270B may not be writable by the application 170. For example, the second set of physical memory pages 270B may include an access permission or protection identifier 320 as ‘Read Only’. Then, the NIC 180 may receive the assignment associated with the receive rings 250 from the device driver 182 (block 524). In an example embodiment, the device driver 182 may notify the NIC 180 of the assignments after the access permissions have been established. The device driver 182 may send a mapping request to the kernel 184 (blocks 526 and 528). In an example embodiment, the device driver 182 may send a mapping request to the kernel 184 once the NIC 180 is initialized. In another example embodiment, the device driver 182 may send the mapping request after the device driver 182 assigns the plurality of rings to physical memory pages. Then, the kernel 184 may receive the mapping request from the device driver 182 (block 530). The kernel 184 may map the transmit rings 240 into the application memory space 142 (block 532). However, all applications 170 in the application memory space 142 may be set to read only, and thus cannot write into the receive rings 250, the application memory space 142 cannot corrupt kernel memory and can only read kernel information. For example, the application memory space 142 may be able to corrupt the transmit ring (e.g., by storing illegal addresses there), but cannot corrupt the receive rings 250. Such a configuration allows the packet processing system to support the kernel 184 and enables better security and improved stability in the face of application memory space bugs or malware.

It will be appreciated that all of the disclosed methods and procedures described herein can be implemented using one or more computer programs or components. These components may be provided as a series of computer instructions on any conventional computer readable medium or machine readable medium, including volatile or non-volatile memory, such as RAM, ROM, flash memory, magnetic or optical disks, optical memory, or other storage media. The instructions may be provided as software or firmware, and/or may be implemented in whole or in part in hardware components such as ASICs, FPGAs, DSPs or any other similar devices. The instructions may be configured to be executed by one or more processors, which when executing the series of computer instructions, performs or facilitates the performance of all or part of the disclosed methods and procedures.

It should be understood that various changes and modifications to the example embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A system comprising:
a network interface controller (NIC);
a memory having a first set of physical memory pages and a second set of physical memory pages;
one or more processors, in communication with the memory; and
a device driver configured to:
initialize the NIC, wherein the device driver is loaded in an operating system (OS) by a kernel of the OS;
assign a plurality of rings to specific physical memory pages, wherein
the plurality of rings include transmit rings and receive rings,
one or more of the transmit rings are utilized by an application in an application memory space,
the transmit rings are assigned to the first set of physical memory pages, and
the first set of physical memory pages is writable by the application; and
initiate a mapping of the transmit rings into the application memory space.

2. The system of claim 1, wherein the device driver is further configured to send a mapping request to the kernel.

3. The system of claim 2, wherein the kernel is configured to:
receive the mapping request from the device driver; and
map the transmit rings into the application memory space.

4. The system of claim 1, wherein the plurality of rings are located in the NIC, the receive rings are assigned to the second set of physical memory pages, and the second set of physical memory pages is not writeable by the application.

5. The system of claim 1, wherein the plurality of rings are located in memory available to the application memory space.

6. The system of claim 1, wherein the mapping includes a page table that maps virtual addresses to physical addresses.

7. The system of claim 1, wherein the device driver is configured to map a transmit request address into the application, and the transmit request address is located on the NIC.

8. A method of packet processing comprising:
initializing, by a device driver, a network interface controller (NIC), wherein the device driver is loaded in an operating system (OS) by a kernel of the OS;
assigning, by the device driver, a plurality of rings to use specific physical memory pages, wherein
the plurality of rings include transmit rings and receive rings,
one or more of the transmit rings are utilized by an application in an application memory space,
the transmit rings are assigned to a first set of physical memory pages,
a first page of the first set of physical pages is writeable by the application; and
initiating, by the device driver, a mapping of the transmit rings into the application memory space.

9. The method of claim 8, wherein initiating the mapping by the device driver includes sending, by the device driver, a mapping request to the kernel.

10. The method of claim 9, further comprising:
responsive to sending the mapping request, receiving, by the kernel, the mapping request from the device driver; and
responsive to receiving the mapping request, mapping, by the kernel, the transmit rings into the application memory space.

11. The method of claim 8, wherein the receive rings are assigned to the second set of physical memory pages, and the second set of physical memory pages is not writeable by the application.

12. The method of claim 8, wherein the plurality of rings are located in one of the NIC, and memory available to the application memory space.

13. The method of claim 8, further comprising restricting, by the device driver, access to the second set of memory pages to a specific type of access by the application in the application memory space.

14. The method of claim 13, wherein the specific type of access is read only access.

15. The method of claim 8, wherein the mapping includes a page table that maps virtual addresses to physical addresses.

16. The method of claim 15, wherein the page table includes access permissions.

17. The method of claim 8, wherein the device driver maps a transmit request address into the application, and the transmit request address is located on the NIC.

18. A non-transitory machine readable medium storing code which, when executed by a computer system, cause the computer system to:
load, by a kernel, a device driver in an operating system;
initialize, by the device driver, a network interface controller (NIC);
assign, by the device driver, transmit rings to a first set of physical memory pages; and
initiate, by the device driver, a mapping of the transmit rings into an application memory space.

19. The non-transitory machine readable medium of claim 18, wherein the computer system is further configured to:
send, by the device driver, a mapping request to the kernel;
responsive to sending the mapping request, receive, by the kernel, the mapping request from the device driver; and
responsive to receiving the mapping request, map, by the kernel, the transmit rings into the application memory space.

20. The non-transitory machine readable medium of claim 18, wherein the computer system is further configured to:
assign, by the device driver, receive rings to a second set of physical memory pages; and
restrict, by the device driver, access to the second set of physical memory pages to a specific type of access by an application in the application memory space.
